(19) United States
(12) Patent Application Publication
(10) Pub. No.: US 2012/0002358 A1
(43) Pub. Date: Jan. 5, 2012

(54) INPUT/OUTPUT UNIT

(75) Inventor: Shoichiro Hayashi, Tokyo (JP)

(73) Assignee: MITSUBISHI ELECTRIC CORPORATION, Tokyo (JP)

(21) Appl. No.: 13/142,235

(22) PCT Filed: Dec. 26, 2008
(86) PCT No.: PCT/JP2008/073823

§ 371 Date: Jun. 24, 2011

(51) Int. Cl. H05K 7/00

(52) U.S. Cl. 361/679.01

(57) ABSTRACT

An input/output unit includes: input/output subunits each including an input/output card that has front-side connectors, which are engaged with back-unit connectors on a back unit of a control device, mounted on a front edge of a substrate and has mounted on a rear edge of the substrate, rear-side connectors to be engaged with connectors of field devices and a card holder that has at a front side, guide shafts to be inserted into guide holes of the back unit and holds the input/output card; and a case which is formed with slots into which the input/output subunits are inserted with a gap, which is formed on a front plate with a long hole into which the back-unit connectors are inserted with a gap and with shaft holes through which the guide shafts are penetrated from inside with a gap, and which is attached to the back unit.

### TECHNICAL FIELD

The present invention relates to an input/output unit that connects a control device such as a numerical control device of a machine tool and a field device such as a sensor, an electrically-operated valve, and a lamp, and performs transmission and reception of an input/output signal.

### BACKGROUND ART

Conventionally, in input/output units that mediate signal transmission and reception between an industrial control device and a field device to be controlled, there is an input/output unit that includes an input/output nest that is bus-connected to the industrial control device; an input/output card that is accommodated in the input/output nest and performs conversion between a signal format used in the industrial control device and a signal format used in the field device; and an interface unit, which is mechanically mounted on the input/output nest, to which a signal line connected to the field device is connected and in which this signal line is electrically connected to the input/output card (see, for example, Patent Document 1).

This conventional input/output unit has a relay substrate (a backboard) interposed between the input/output card and a back unit of the industrial control device. Furthermore, on this relay substrate, there are mounted a connector (one) connected to a connector on the back unit, and plural (four) connectors connected to plural (four) input/output cards.

When an input/output subunit is connected to the back unit, the relay substrate is held in an input/output nest as a resin molding, and the input/output nest is first fitted to the back unit with screws. At this time, the connectors of the relay substrate within the input/output nest and the connector on the back unit are simultaneously engaged with each other.

Within the input/output nest fitted to the back unit, a plurality of connectors of the relay substrate to be connected to the input/output card are arranged. The input/output cards are inserted one by one along a card insertion slot of the input/output nest that is formed of a resin molding, thereby performing connector connection.

Patent Document 1: Japanese Patent Application Laid-open No. H06-244570

### DISCLOSURE OF INVENTION

### Problems to be Solved by the Invention

However, according to the conventional input/output subunit described above, after the input/output nest is fitted to the back unit, plural (four) input/output cards further need to be inserted one by one to perform connector connection, and therefore this has a problem in that there are many assembly man-hours. Further, a relay substrate (a backboard) to connect the input/output card and the back unit is necessary, and this has a problem in that reliability of electric connection is low and its cost increases.

The present invention has been achieved in view of the above problems, and an object of the present invention is to obtain a low-cost input/output unit having a small number of assembly man-hours with high reliability of electric connection.

### Means for Solving Problem

To solve the problem above and achieve the object, an input/output unit that includes front-side connectors engaged with a plurality of back-unit connectors arranged in parallel on a back unit of a control device and mediates transmission and reception of a signal between the control device and a plurality of field devices, the input/output unit including: a plurality of input/output subunits each including an input/output card that has the front-side connector mounted on a front edge of a substrate and has mounted on a rear edge of the substrate a plurality of rear-side connectors to be engaged with connectors of the field devices, and is installed thereon an electronic circuit that mediates the transmission and reception of a signal, and a card holder that has at a front side a plurality of guide shafts to be inserted into guide holes of the back unit and holds the input/output card; and a case which is formed in a box shape with a back surface opened, which is formed with a plurality of slots into which the input/output subunits are inserted with a gap held between an inner surface and the input/output subunits, which is formed on a front plate with a long hole into which the back-unit connectors are inserted from outside with a gap held between an inner surface and the back-unit connectors and with shaft holes through which the guide shafts are penetrated from inside with a gap held between an inner surface and the guide shafts, and which is attached to the back unit with the input/output subunits being held within the respective slots.

### Effect of the Invention

The input/output unit according to the present invention has a small number of assembly man-hours, has high reliability of electric connection, and is manufactured at a low cost.

### BRIEF DESCRIPTION OF DRAWINGS

FIG. 1 is a perspective view of an input/output card of an input/output unit according to an embodiment of the present invention.

FIG. 2 is a perspective view of a card holder according to the embodiment.

FIG. 3 is a perspective view showing a state before input/output subunits according to the embodiment are inserted into a case.

FIG. 4 is a front perspective view showing a state in which the input/output subunits according to the embodiment are inserted into the case.

FIG. 5 is a perspective view showing a state before the input/output unit according to the embodiment is fitted to a back unit.

FIG. 6 is a rear view of the input/output unit according to the embodiment.

FIG. 7 is a cross-sectional view taken along a line A-A in FIG. 6.

FIG. 8 is an enlarged view of a part D in FIG. 7.

FIG. 9 is a cross-sectional view taken along a line B-B in FIG. 6.

FIG. 10 is an enlarged view of a part E in FIG. 9.

FIG. 11 is a cross-sectional view taken along a line C-C in FIG. 6.

### EXPLANATIONS OF LETTERS OR NUMERALS

10 Input/output card
11 Substrate
11a Reference hole
11b Longitudinal reference hole
11c Fastening holes
12 Front-side connector
13 Rear-side connector
14 Electronic circuit
20 Card holder
20a Back plate
20b Long hole
20c Top plate
20d Bottom plate
20e Snap-fit
20f Gripper
20g Side plate
20h Positioning pin
20i Front plate
20j Notch
20k Guide shaft
20m Locking claw
20n Protruding ridge (protrusion)
20p Base
20r Screw hole
20s Snap-fit
30 Input/output subunit
40 Case
40a Top plate
40b Bottom plate
40c Groove
40d Slot
40e Guide portion
40f Snap-fit engaging portion
40g Locking hole
40h Supporting groove
40i Front plate
40j Long hole
40k Shaft hole
40m, 40n Screw through-hole
40p Side plate
40s Gap
40t Gap
41 Screw
50 Back unit
50a Guide hole
50b Screw hole
51 Back-unit connector
91 Input/output unit

### BEST MODE(S) FOR CARRYING OUT THE INVENTION

Exemplary embodiments of an input/output card according to the present invention will be explained below in detail with reference to the accompanying drawings. The present invention is not limited to the embodiments.

### Embodiment

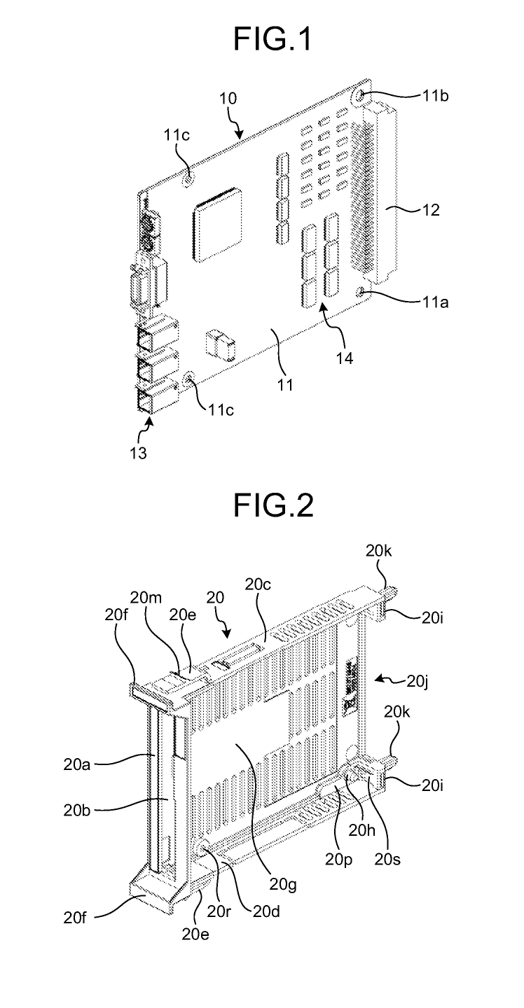

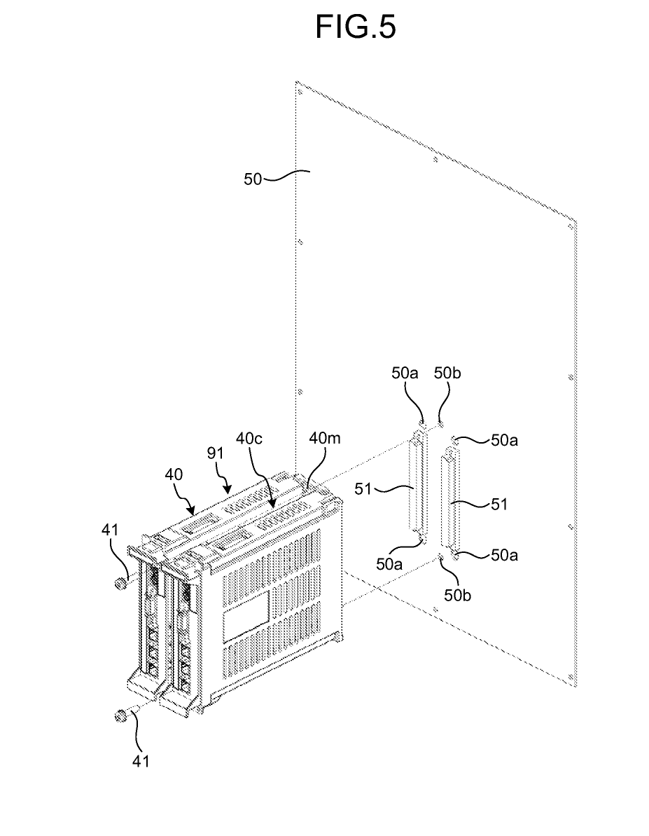

FIG. 1 is a perspective view of an input/output card of an input/output unit according to an embodiment of the present invention. As shown in FIG. 1, an input/output card 10 includes: a rectangular substrate 11; a front-side connector 12 that is mounted on a front edge of a surface of the substrate 11 and is engaged with back-unit connectors 51 (see FIG. 5) described later; a plurality of rear-side connectors 13 that are mounted on a rear edge of the surface of the substrate 11 and are engaged with connectors of field devices (a sensor, an electrically-operated valve, a lamp or the like, which are not shown); and an electronic circuit 14 that is mounted on the substrate 11, electrically connects the front-side connector 12 and the rear-side connectors 13, and performs conversion between a signal format that is used in a control device (not shown) and a signal format that is used in the field devices.

A reference hole 11a for positioning the input/output card 10 on a card holder (see FIG. 2) described later is provided at a lower part of the front edge of the substrate 11, and a longitudinal reference hole 11b is provided at an upper part of the front edge. Fastening holes 11c are provided at upper and lower parts at a rear portion of the substrate 11.

FIG. 2 is a perspective view of a card holder according to the present embodiment. As shown in FIG. 2, a card holder 20 is molded by a resin in a thin rectangular-solid box shape having one side surface opened. A back plate 20a is formed with a long hole 20b through which the rear-side connectors 13 of the input/output card 10 stick out.

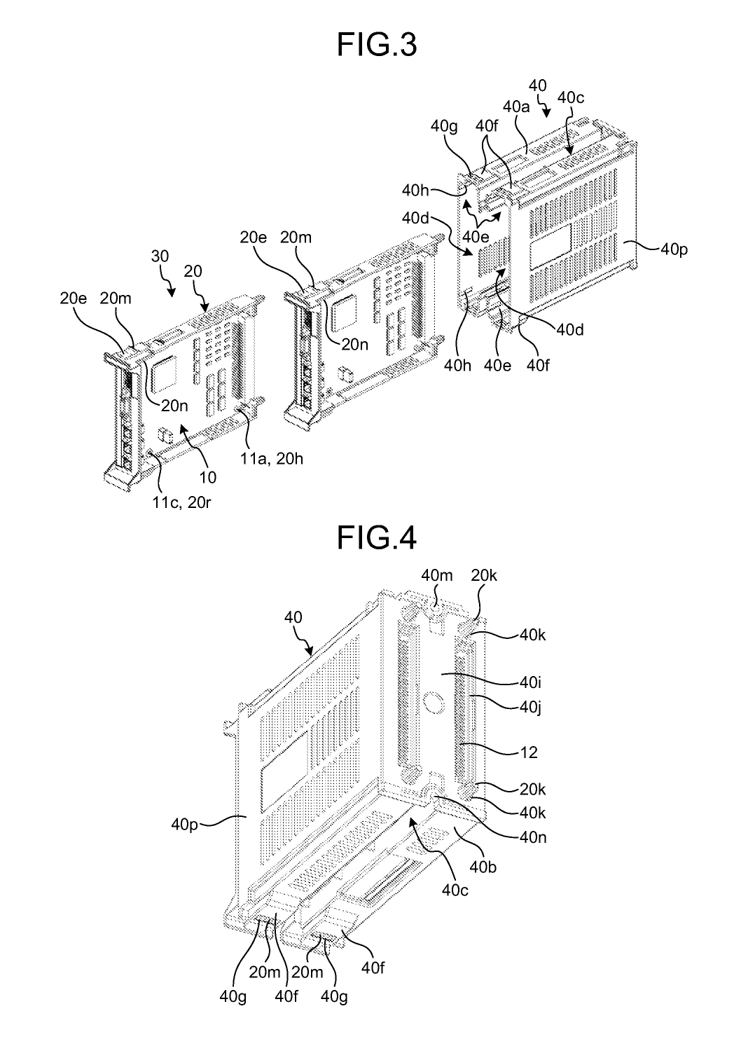

Substantially L-shaped snap-fits 20e are provided at outside of a rear portion of a top plate 20c and a bottom plate 20d. Locking claws 20m are provided on the snap-fits 20e. Protruding ridges 20n (see FIG. 3) are provided as protrusions at both sides of the rear portion of the top plate 20c and the bottom plate 20d. Grippers 20f are provided at a rear end part of the top plate 20c and the bottom plate 20d.

Bases 20p on which the input/output card 10 is set are formed at upper and lower parts of a front edge of a side plate 20g. Positioning pins 20h that are engaged with the reference hole 11a and the longitudinal reference hole 11b of the substrate 11 and position the input/output card 10 on the card holder 20 are provided on the bases 20p. Snap-fits 20s that are engaged with a front edge of the input/output card 10, which is engaged with the positioning pins 20h, for preventing disengagement of the input/output card 10 are provided at a rear side of a front plate 20i in front of the positioning pins 20h. Screw holes 20r are provided on a base at upper and lower parts of a rear portion of the side plate 20g.

A major portion of the front plate 20i excluding an upper part and a lower part is formed with a notch 20j through which the front-side connector 12 of the input/output card 10 comes out. The upper part and the lower part of the front plate 20i are provided with two tapered guide shafts 20k, which are inserted into guide holes 50a provided near above and below the back-unit connectors 51 (see FIG. 5) on a back unit 50. Multiple ventilation holes are provided on the side plate 20g, the top plate 20c, and the bottom plate 20d.

FIG. 3 is a perspective view of a state before the input/output subunits according to the present embodiment are inserted into a case. As shown in FIG. 3, each input/output subunit 30 includes the card holder 20 formed in a thin rectangular-solid box shape having one side surface opened, and the input/output card 10 positioned and fixed on the side plate 20g of the card holder 20.

The input/output card 10 is set on the bases 20p formed on the side plate 20g of the card holder 20. The reference hole 11a and the longitudinal reference hole 11b of the substrate 11 are engaged with the positioning pins 20h. The front edge of the input/output card 10 is locked with the snap-fits 20s, and the input/output card 10 is fastened to the screw holes 20r through the fastening holes 11c with screws (not shown).

The input/output card 10 is positioned in a perpendicular direction with the card holder 20 by being set on the bases 20p. The input/output card 10 is positioned in forward and backward directions and in upper and lower directions by engaging the reference hole 11a and the longitudinal reference hole 11b with the positioning pins 20h. The longitudinal reference hole 11b absorbs manufacturing errors of a pitch between the positioning pins 20h and a pitch between the reference holes 11a and 11b.

In a state in which the input/output card 10 is positioned and fixed on the card holder 20, the rear-side connectors 13 of the input/output card 10 stick out from the long hole 20b that is formed on the back plate 20a of the card holder 20. The front-side connector 12 sticks out from the notch 20j of the front plate 20i of the card holder 20.

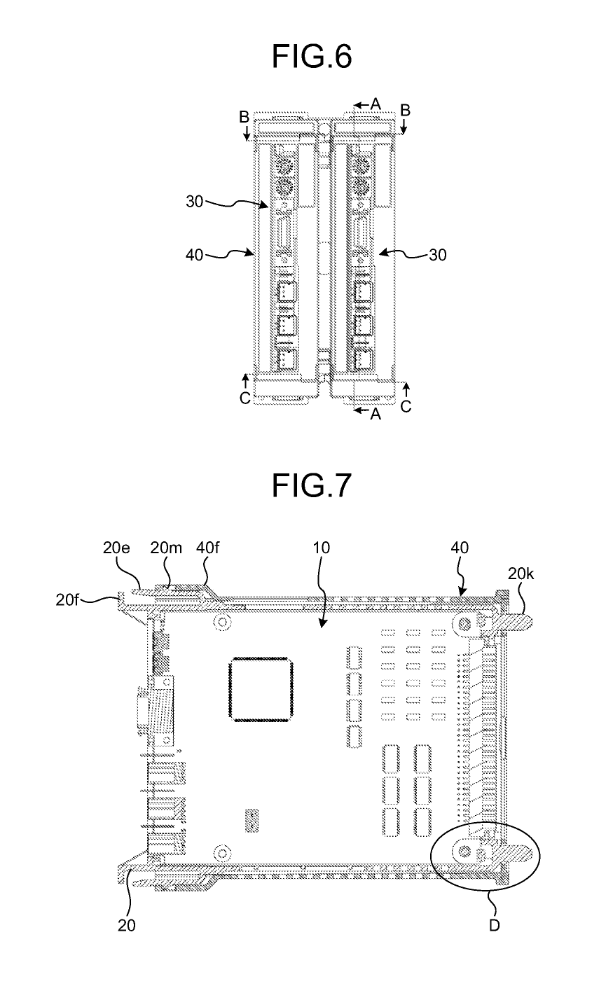

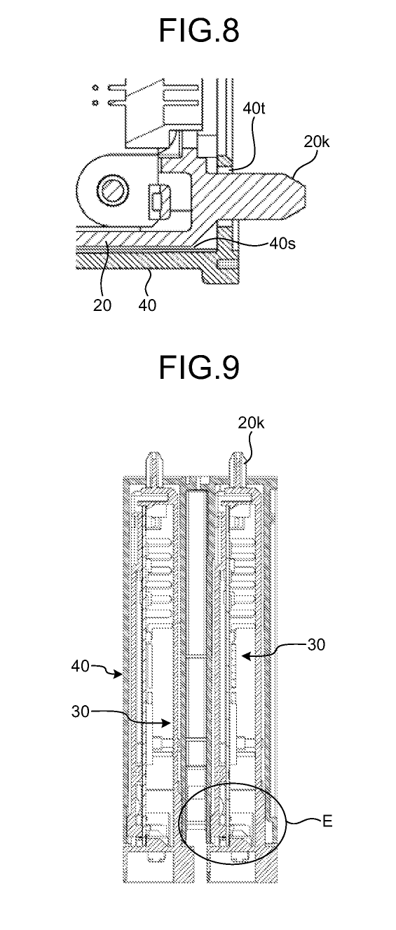

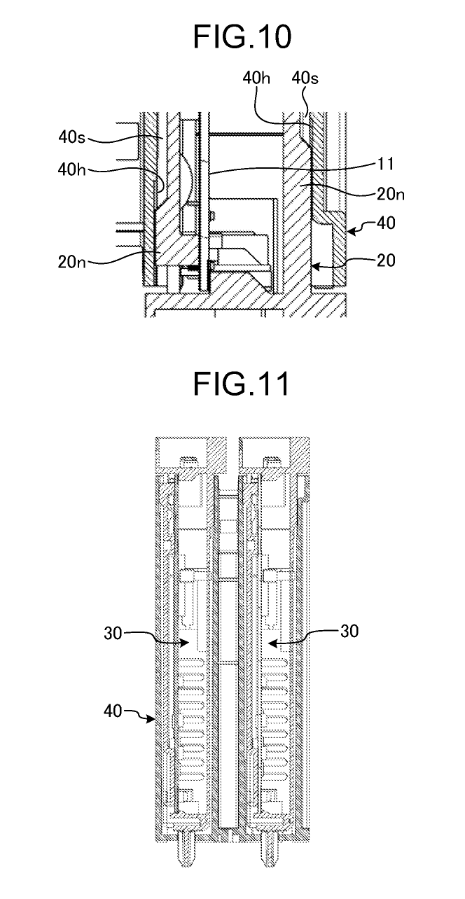

FIG. 4 is a front perspective view of a state that the input/output subunits according to the present embodiment are inserted into the case; FIG. 5 is a perspective view of a state before the input/output unit according to the present embodiment is fitted to the back unit; FIG. 6 is a rear view of the input/output unit according to the present embodiment; FIG. 7 is a cross-sectional view along a line A-A in FIG. 6; FIG. 8 is an enlarged view of a part D in FIG. 7; FIG. 9 is a cross-sectional view along a line B-B in FIG. 6; FIG. 10 is an enlarged view of a part E in FIG. 9; and FIG. 11 is a cross-sectional view along a line C-C in FIG. 6.

As shown in FIGS. 3 and 4, a case 40 is molded by a resin in a rectangular-solid box shape having a back surface opened. At centers in a width direction of a top plate 40a and a bottom plate 40b, U-shaped grooves 40c are formed over the entire length in forward and backward directions. An inner space of the case 40 is divided into two slots 40d by the grooves 40c.

U-shaped guide units 40e that guide an insertion of the input/output subunits 30 are formed above and below the slots 40d, respectively. The sizes of inner surface of the slots 40d in vertical and horizontal direction are formed approximately 2 millimeter larger than the external sizes of the card holder 20 in vertical and horizontal direction. Therefore, a gap 40s (see FIGS. 8 and 10) of approximately 1 millimeter is present over the entire periphery between an inner surface of the slots 40d (the guide units 40e) and the card holder 20.

Snap-fit engaging units 40f that are engaged with the snap-fits 20e of the card holder 20 and elastically hold a rear portion of the input/output cards 30 are formed at a rear end part of the guide units 40e. The snap-fit engaging units 40f are provided with locking holes 40g that lock the locking claws 20m provided on the snap-fits 20e and prevent disengagement of the input/output subunits 30 from the slots 40d.

As shown in FIGS. 3 and 10, a plurality of supporting grooves 40h, which are engaged with the protruding ridges 20n as protrusions provided at a rear portion of the card holder 20 and point support the rear portion of the input/output subunits 30, are provided at both sides of a rear portion of the guide units 40e.

As shown in FIG. 4, on a front plate 40i of the case 40, there are provided two long holes 40j through which the back-unit connectors 51 (see FIG. 5) can be inserted corresponding to two slots 40d, respectively, and a total of four shaft holes 40k through which the guide shafts 20k of the input/output subunits 30 are penetrated. The shaft holes 40k are provided near above and below the long holes 40j.

Vertical and horizontal inner surface sizes of the long holes 40j are formed approximately 2 millimeters larger vertically and horizontally than external sizes of the back-unit connectors 51. A gap of approximately 1 millimeter is present over the entire periphery between an inner surface of the long holes 40j and the unit connectors 51 that are inserted into the long holes 40j. An inner diameter size of the shaft holes 40k is formed approximately 2 millimeters larger than an external diameter size of the guide shafts 20k. A gap 40t (see FIG. 8) of approximately 1 millimeter is present over the entire periphery between an inner surface of the shaft holes 40k and the guide shafts.

On the front plate 40i in front of the grooves 40c, screw through-holes 40m and 40n through which screws 41 for fastening the case 40 to screw holes 50b of the back unit 50 are inserted are provided. Multiple ventilation holes are provided on the top plate 40a, the bottom plate 40b, and side plates 40p of the case 40.

As shown in FIGS. 6 to 11, the input/output subunits 30 are inserted into the two slots 40d of the case 40, respectively, and the front plate 20i of the card holder 20 is brought into contact with an inner surface of the front plate 40i of the case 40. As a result, the guide shafts 20k of the input/output subunits 30 are penetrated through the shaft holes 40k of the front plate 40i. In this case, the gap 40s (see FIGS. 8 and 10) of approximately 1 millimeter is present between an inner surface of the slots 40d (the guide units 40e) and the input/output subunits 30, and the gap 40t (see FIG. 8) of approximately 1 millimeter is present between the inner surface of the shaft holes 40k and the guide shafts 20k.

The snap-fits 20e provided at outside of the rear portion of the top plate 20c and the bottom plate 20d of the card holder 20 are engaged with the snap-fit engaging units 40f formed above and below a rear end of the slots 40d (the guide units 40e) of the case 40, and the snap-fits 20e are elastically supported. The locking claws 20m provided on the snap-fits 20e are engaged in the locking holes 40g provided on the snap-fit engaging units 40f, thereby preventing disengagement of the input/output subunits 30 from the case 40.

Further, the plural protruding ridges 20n as protrusions provided at both sides of the rear portion of the top plate 20c and the bottom plate 20d of the card holder 20 are engaged with the supporting grooves 40h that are provided at both sides of the rear portion of the guide units 40e. The input/output subunits 30 have the protruding ridges 20n point-supported by the supporting grooves 40h, and the front part thereof is swingable in vertical and horizontal directions within the gap of approximately 1 millimeter between the slots 40d and the inner surface.

A gap between the protruding ridges 20n and an inner surface of the supporting grooves 40h is set at approximately 0.2 millimeter. Therefore, the protruding ridges 20n are constrained in vertical and horizontal directions by the supporting grooves 40h, and become in a point-supported state. An input/output unit 91 includes the case 40 explained above and the input/output subunits 30 inserted and held in the case 40. Regarding the input/output subunits 30, the protruding ridges 20n provided at a rear portion are point-supported by the supporting grooves 40h, and the front part swings in vertical and horizontal directions. Therefore, a swing angle is small.

When the guide shafts 20k of the input/output unit 91 are inserted into the guide holes 50a of the back unit 50, the back-unit connectors 51 are engaged with the front-side connectors 12 of the input/output subunits 30.

In this case, even when an arranged position of two back-unit connectors 51 arranged in parallel in the back unit 50 are deviated due to an assembly error, the guide shafts 20k and the front-side connectors 12 follow the deviated back-unit connectors 51 and swing at a small inclination angle in the slots 40d, and the back-unit connectors 51 and the front-side connectors 12 can be engaged together flexibly.

In this state, the screws 41 are screwed into the screw holes 50b of the back unit 50 through the screw through-holes 40m and 40n of the case 40, and the input/output unit 91 is attached to the back unit 50.

In the embodiment of the present invention, an example of inserting and holding two input/output subunits 30 into one case 40 is explained. Alternatively, three or more input/output subunits 30 can be inserted and held in one case.

As explained above, the input/output unit 91 according to the embodiment does not require a relay substrate to connect the input/output card 10 and the back unit 50. Therefore, the input/output unit 91 has a small number of assembly man-hours, has high reliability of electric connection, and is at a low cost.

### INDUSTRIAL APPLICABILITY

As described above, the input/output unit according to the present invention is useful for an input/output unit such as a numerical control device of a machine tool.

1. An input/output unit that comprises front-side connectors engaged with a plurality of back-unit connectors arranged in parallel on a back unit of a control device and mediates transmission and reception of a signal between the control device and a plurality of field devices,
the input/output unit comprising:
a plurality of input/output subunits each including
an input/output card that has the front-side connector mounted on a front edge of a substrate and has mounted on a rear edge of the substrate a plurality of rear-side connectors to be engaged with connectors of the field devices, and is installed thereon an electronic circuit that mediates the transmission and reception of a signal, and
a card holder that has at a front side a plurality of guide shafts to be inserted into guide holes of the back unit and holds the input/output card; and
a case which is formed in a box shape with a back surface opened, which is formed with a plurality of slots into which the input/output subunits are inserted with a gap held between an inner surface and the input/output subunits, which is formed on a front plate with a long hole into which the back-unit connectors are inserted from outside with a gap held between an inner surface and the back-unit connectors and with shaft holes through which the guide shafts are penetrated from inside with a gap held between an inner surface and the guide shafts, and which is attached to the back unit with the input/output subunits being held within the respective slots.

2. The input/output unit according to claim 1, wherein the card holder includes at a rear portion a plurality of protrusions that become supporting points, a plurality of supporting grooves that support the protrusions respectively are provided at a rear portion of the slots of the case, and
the input/output subunits are configured such that the protrusions are supported by the supporting grooves, and a front part swings vertically and horizontally within the gap.

3. The input/output unit according to claim 2, wherein the card holder
is formed in a thin rectangular-solid box shape having one side surface opened, and is formed with
a long hole formed on a back plate through which the rear-side connectors of the input/output card stick out,
snap-fits provided at outside of a rear portion of a top plate and a bottom plate,
locking claws provided on the snap-fits, and
protruding ridges provided as the protrusions at both sides of the rear portion of the top plate and the bottom plate.

4. The input/output unit according to claim 3, wherein snap-fit engaging units that are engaged with the snap-fits of the card holder are formed above and below a rear end of the slots of the case, and locking holes that prevent disengagement of the input/output subunits by locking the locking claws provided on the snap-fits are provided in the snap-fit engaging units.
